(19) United States
(12) Patent Application Publication
(10) Pub. No.: US 2011/0066386 A1
(43) Pub. Date: Mar. 17, 2011

(54) ANESTHETIC SENSING OPTICAL MICROFLUIDIC CHIP SYSTEM

(76) Inventors: Chien-Chong Hong, Zhubei City (TW); Po-Hsiang Chang, Kaohsiung City (TW); Chih-Chung Lin, Guishan Township (TW)

(21) Appl. No.: 12/560,836

(22) Filed: Sep. 16, 2009

(51) Int. Cl. G06F 19/00; H01L 31/12

(52) U.S. Cl. 702/23; 250/552

(57) ABSTRACT

The invention discloses an anesthetic sensing optical microfluidic chip system. The anesthetic sensing optical microfluidic chip system includes a biochip, a light source, and a detector. The biochip includes a substrate, a micro-channel, and a molecularly imprinted biosensor. The micro-channel is bonded beyond the substrate. The molecularly imprinted biosensor is disposed in the micro-channel, and a surface of the molecularly imprinted biosensor has a plurality of imprinted sites. When a sample including a plurality of anesthetic molecules is injected into the micro-channel and flowing through the surface of the molecularly imprinted biosensor, some of the anesthetic molecules are captured by the imprinted sites. The light source emits a sensing light to the plastic biochip, and the detector receives the sensing light passing through the imprinted sites on the surface of the molecularly imprinted biosensor and generates a detecting result based on the received sensing light.

### BACKGROUND OF THE INVENTION

1. Field of the Invention

The present invention relates to a microfluidic system, and more particularly, to an anesthetic sensing optical microfluidic chip system.

2. Description of the Prior Art

Recently, since the anesthetic is very important in the clinical medicine region, the researches related to the anesthetic have been increased. For example, propofol (2,6-di-isopropylphenol) is an intravenous anesthetic and widely used in induction of anesthesia, total intravenous anesthesia and sedation of intensive care unit patients.

In order to detect the concentration of propofol in blood of human body, the high-performance liquid chromatography and/or the high-performance gas chromatography are conventionally used. However, not only the high-performance liquid chromatography and/or gas chromatography are very expensive and not ease of access, but also the detecting processes performed by the high-performance liquid chromatography and/or gas chromatography are time-consuming and not a real-time detection. Therefore, the conventional high-performance liquid chromatography and/or gas chromatography are not convenient for the doctor and patient to use. Clinically, a more convenient access to monitor the propofol concentration in blood is needed to avoid the adverse effects produced by excessive or insufficient propofol.

Therefore, the invention provides an anesthetic sensing optical microfluidic chip system to solve the aforementioned problems.

### SUMMARY OF THE INVENTION

The invention provides an anesthetic sensing optical microfluidic chip system. One preferred embodiment of the invention is an anesthetic sensing optical microfluidic chip system. In this embodiment, the anesthetic sensing optical microfluidic chip system includes a biochip, a light source, and a detector. The biochip includes a substrate, a micro-channel, and a molecularly imprinted biosensor. The micro-channel is bonded beyond the substrate. The molecularly imprinted biosensor is disposed in the micro-channel, and a surface of the molecularly imprinted biosensor has a plurality of imprinted sites.

When a sample including a plurality of anesthetic molecules is injected into the micro-channel and flowing through the surface of the molecularly imprinted biosensor, some of the anesthetic molecules are captured by the imprinted sites. The light source emits a sensing light to the plastic biochip, and the detector receives the sensing light passing through the imprinted sites on the surface of the molecularly imprinted biosensor and generates a detecting result based on the received sensing light.

In practical applications, the anesthetic is propofol (2,6-di-isopropylphenol) and the molecularly imprinted biosensor is made of polymer. The plurality of imprinted sites on the surface of the molecularly imprinted biosensor is formed by processing the steps of polymer combination, polymerization, and extraction in order.

Compared with the prior art, the novel low-cost anesthetic sensing optical microfluidic chip system with molecularly imprinted biosensor disclosed by this invention has many advantages of compact size, high sensitivity, low cost, and fast response. With this anesthetic sensing optical microfluidic chip system, a real-time propofol concentration detection can be achieved and the propofol concentration can be also adjusted according to the result of the real-time propofol concentration detection. Additionally, since the biochip used in the anesthetic sensing optical microfluidic chip system is cheap and can be disposable, the mutual contamination occurred between several samples in the same large-scale liquid chromatography and/or gas chromatography can be effectively avoided. By doing so, the doctor can clinically control the propofol concentration more accurately and the safety of the patient can be further ensured.

The objective of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1A illustrates a scheme diagram of the anesthetic sensing optical microfluidic chip system according to an embodiment of the present invention.

FIG. 1B illustrates a scheme diagram of operating the anesthetic sensing optical microfluidic chip system shown in FIG. 1A to generate a detecting result based on the received sensing light.

FIG. 2 illustrates a top view of the micro-channel on the biochip in the anesthetic sensing optical microfluidic chip system.

FIG. 3A illustrates a top view of the imprinted sites on the molecularly imprinted biosensor of the biochip before the anesthetic molecules are injected onto the molecularly imprinted biosensor.

FIG. 3B illustrates a top view of the injected anesthetic molecules being captured by the imprinted sites on the molecularly imprinted biosensor of the biochip.

FIG. 4A˜FIG. 4C illustrate the steps of manufacturing the biochip of the anesthetic sensing optical microfluidic chip system.

FIG. 5A illustrates the dynamic measurement results of the anesthetic propofol samples at different concentrations.

FIG. 5B illustrates the measurement results of the anesthetic propofol samples at t=60^{th} second.

### DETAILED DESCRIPTION OF THE INVENTION

The invention provides a novel low-cost anesthetic sensing optical microfluidic chip system with molecularly imprinted biosensor. With this anesthetic sensing optical microfluidic chip system, a real-time propofol concentration detection can be achieved and the propofol concentration can be adjusted according to the result of the real-time propofol concentration detection. Therefore, the doctor can clinically control the propofol concentration more accurately and the safety of the patient can be further ensured.

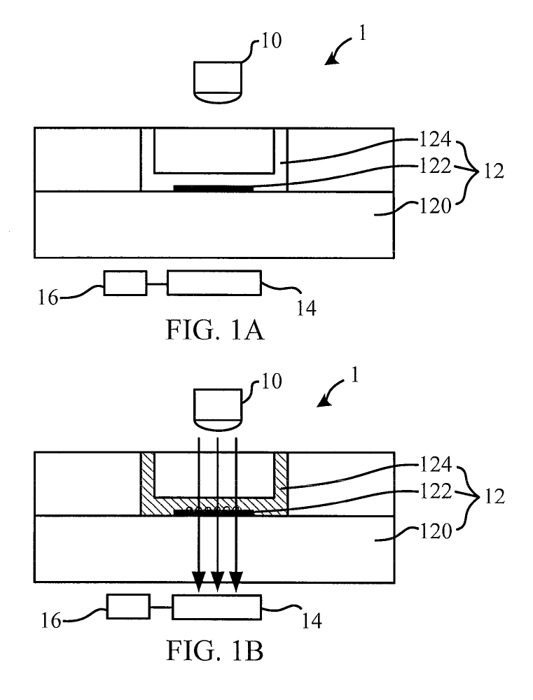

An embodiment of the present invention is an anesthetic sensing optical microfluidic chip system. Please refer to FIG. 1A. FIG. 1A illustrates a scheme diagram of the anesthetic sensing optical microfluidic chip system according to the embodiment of the present invention.

As shown in FIG. 1A, the anesthetic sensing optical microfluidic chip system 1 includes a light source 10, a biochip 12, a detector 14, and a processor 16. The biochip 12 includes a substrate 120, a molecularly imprinted biosensor 122, and a micro-channel 124. The micro-channel 124 is bonded beyond a first surface of the substrate 120. The molecularly imprinted biosensor 122 is disposed in the micro-channel 124. The detector 14 is disposed under a second surface of the substrate 120, and the second surface is opposite to the first surface. The processor 16 is coupled to the detector 14.

In practical applications, the light source 10 can be a laser diode; the substrate 120 of the biochip 12 can be made of plastic material; the detector 14 can be a photodetector; the processor 16 can be a computer; the molecularly imprinted biosensor 122 can be made of polymer; the micro-channel 124 can be in the form of U. However, it should be noticed that the above-mentioned conditions are only examples, and there are still other possibilities, not limited to these cases.

Please refer to FIG. 1B. FIG. 1B illustrates a scheme diagram of operating the anesthetic sensing optical microfluidic chip system 1 to generate a detecting result based on the received sensing light. As shown in FIG. 1B, a sample including anesthetic molecules is injected into the micro-channel 124 and it will flow through a surface of the molecularly imprinted biosensor 122.

It should be noticed that there are imprinted sites located on the surface of the molecularly imprinted biosensor 122, therefore, when the sample including anesthetic molecules flows through a surface of the molecularly imprinted biosensor 122, some of the anesthetic molecules will be captured by the imprinted sites located on the surface of the molecularly imprinted biosensor 122. At this time, the molecularly imprinted biosensor 122 becomes as a sample to be light-detected, and it is ready to be light-detected. In fact, the anesthetic molecules can be the propofol (2,6-di-isopropylphenol) molecules, but not limited to this case.

Then, the anesthetic sensing optical microfluidic chip system 1 will start to detect the anesthetic concentration of the anesthetic molecules captured on the molecularly imprinted biosensor 122. In the anesthetic sensing optical microfluidic chip system 1, the light source 10 will emit a sensing light to the plastic biochip 12. In fact, since propofol can be detected at the sensing light of 655 nm wavelength, the light source 10 can emit the sensing light of 655 nm wavelength, but not limited to this case.

As shown in FIG. 1B, the sensing light emitted from the light source 10 will pass through the anesthetic molecules captured by the imprinted sites on the molecularly imprinted biosensor 122, the molecularly imprinted biosensor 122, and the substrate 120. And then, the sensing light will be received by the detector 14. After that, the detector 14 will generate a detecting result based on the received sensing light. And then, the processor 16 will receive the detecting result from the detector 14 and process the detecting result to generate a real-time anesthetic concentration information according to the detecting result. Therefore, the anesthetic concentration can be adjusted according to the real-time anesthetic concentration information generated by the processor 16.

In practical applications, the detecting result generated by the detector 14 can relate to a measured voltage drop of the detector 14, and the measured voltage drop of the detector 14 can relate to the anesthetic concentration of the light-detected sample.

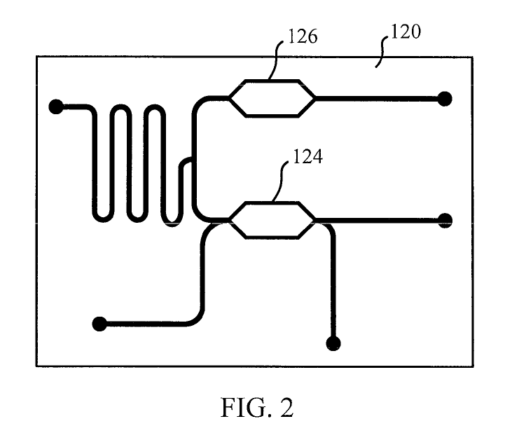

Please refer to FIG. 2. FIG. 2 illustrates a top view of the micro-channel 124 on the substrate 120 of the biochip 12 in the anesthetic sensing optical microfluidic chip system 1. As shown in FIG. 2, it can be found that the micro-channel 124 shown in FIG. 1A and FIG. 1B is actually a detection microchamber, and the sample is injected into the detection microchamber 124 and the molecule recognition is processed in the detection microchamber 124. Additionally, there is still another microchamber called a reference microchamber used as a reference.

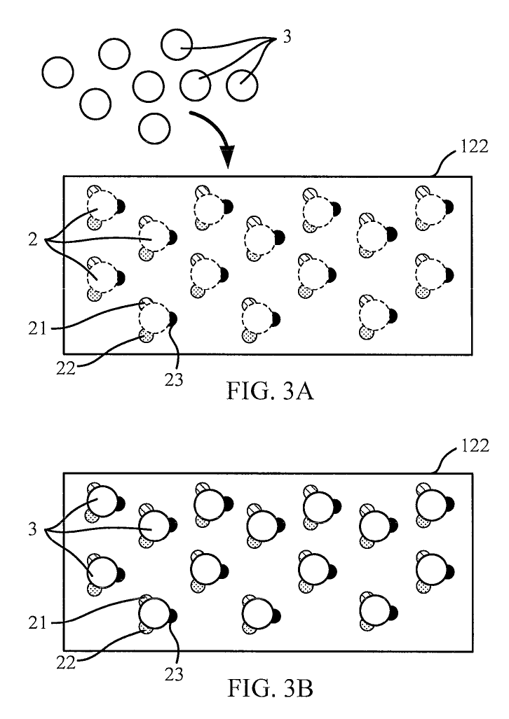

Please refer to FIG. 3A. FIG. 3A illustrates a top view of the imprinted sites on the molecularly imprinted biosensor 122 of the biochip 12 before the anesthetic molecules 3 are injected onto the molecularly imprinted biosensor 122. As shown in FIG. 3A, there are many imprinted sites 2 located on the surface of the molecularly imprinted biosensor 122, and each of these imprinted sites 2 is formed by the molecules 21, 23, and 23.

When the anesthetic molecules 3 are injected into the micro-channel 124 and flow through the surface of the molecularly imprinted biosensor 122 located in the micro-channel 124, some of the anesthetic molecules 3 will be captured by the imprinted sites 2, as shown in FIG. 3B.

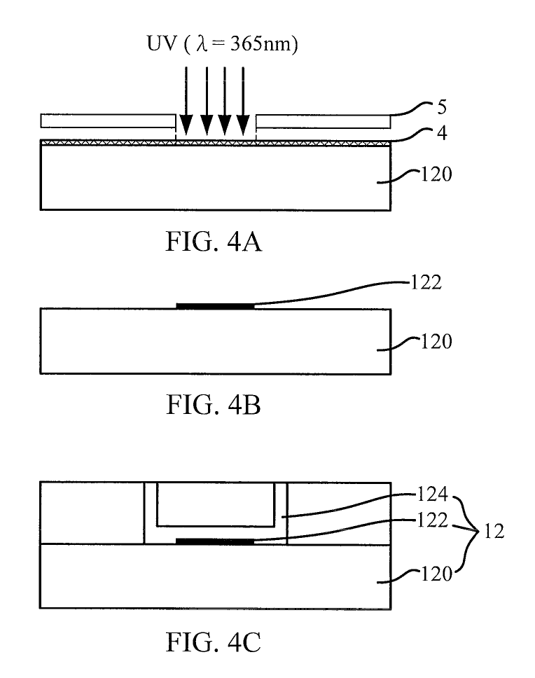

Please refer to FIG. 4A˜FIG. 4C. FIG. 4A˜FIG. 4C illustrate the steps of manufacturing the biochip 12 of the anesthetic sensing optical microfluidic chip system 1. As shown in FIG. 4A and FIG. 4B, after the steps of processing polymer combination, polymerization, and extraction in order, the imprinted sites will be formed on the surface of the molecularly imprinted biosensor 122 on the substrate 120. Then, the molecularly imprinted biosensor 122 and the substrate 120 will be bonded with the microchannel 124, so that the biochip 12 of the anesthetic sensing optical microfluidic chip system 1 will be manufactured.

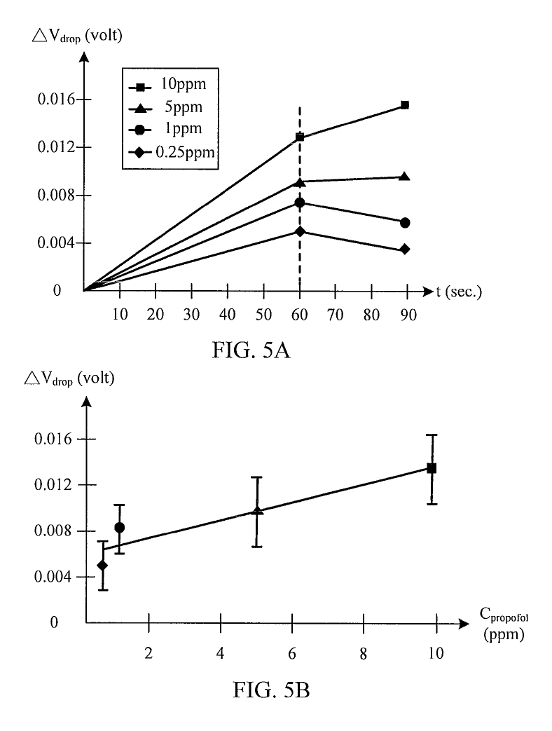

Please refer to FIG. 5A. FIG. 5A illustrates the dynamic measurement results of the anesthetic propofol samples at different propofol concentrations. In the experiments, the anesthetic sensing optical microfluidic chip system 1 is connected to a power supply and a PC-based DAQ system for real-time continuous data recording. As shown in FIG. 5A, once the propofol concentration is higher, the measured voltage drop □V_{drop} of the photodetector will be also higher.

Please refer to FIG. 5B. FIG. 5B illustrates the measurement results of the anesthetic propofol samples at t=60^{th} second. As shown in FIG. 5B, at a constant time point, there will be approximately a linear relationship between the measured voltage drop □V_{drop} of the photodetector and the propofol concentration C_{propofol}.

In practical applications, the anesthetic sensing optical microfluidic chip system 1 can further include a display (not shown in the figures). The display is coupled to the processor 16, if the processor 16 detects that the anesthetic concentration of the sample is over a default threshold value, the display will show a warning message, so that the doctor can control the propofol concentration in-time according to the warning message shown on the display.

To sum up, the novel low-cost anesthetic sensing optical microfluidic chip system with molecularly imprinted biosensor disclosed by this invention has many advantages of compact size, high sensitivity, low cost, and fast response. With this anesthetic sensing optical microfluidic chip system, a real-time propofol concentration detection can be achieved and the propofol concentration can be also adjusted according to the result of the real-time propofol concentration detection.

Additionally, since the biochip used in the anesthetic sensing optical microfluidic chip system is cheap and can be disposable, the mutual contamination occurred between several samples in the same large-scale liquid chromatography and/or gas chromatography can be effectively avoided. By doing so, the doctor can clinically control the propofol concentration more accurately and the safety of the patient can be further ensured.

Although the present invention has been illustrated and described with reference to the preferred embodiment thereof, it should be understood that it is in no way limited to the details of such embodiment but is capable of numerous modifications within the scope of the appended claims.

What is claimed is:

1. An anesthetic sensing optical microfluidic chip system, comprising:
a biochip, comprising:
a substrate;
a micro-channel, bonded beyond a first surface of the substrate; and
a molecularly imprinted biosensor, disposed in the micro-channel, a surface of the molecularly imprinted biosensor having a plurality of imprinted sites, when a sample comprising a plurality of anesthetic molecules is injected into the micro-channel and flowing through the surface of the molecularly imprinted biosensor, some of the anesthetic molecules being captured by the imprinted sites; and
a light source, for emitting a sensing light to the plastic biochip; and
a detector, disposed under a second surface of the substrate opposite to the first surface, for receiving the sensing light passing through the imprinted sites on the surface of the molecularly imprinted biosensor and generating a detecting result based on the received sensing light.

2. The anesthetic sensing optical microfluidic chip system of claim 1, wherein the substrate of the biochip is made of plastic material.

3. The anesthetic sensing optical microfluidic chip system of claim 1, wherein the light source is a laser diode.

4. The anesthetic sensing optical microfluidic chip system of claim 1, wherein the detector is a photodetector.

5. The anesthetic sensing optical microfluidic chip system of claim 1, wherein the detecting result relates to a measured voltage drop of the detector, and the measured voltage drop of the detector relates to the anesthetic concentration of the sample.

6. The anesthetic sensing optical microfluidic chip system of claim 1, wherein the anesthetic is propofol (2,6-di-isopropylphenol).

7. The anesthetic sensing optical microfluidic chip system of claim 6, wherein propofol can be detected by the detector at the sensing light of 655 nm wavelength.

8. The anesthetic sensing optical microfluidic chip system of claim 1, wherein the molecularly imprinted biosensor is made of polymer.

9. The anesthetic sensing optical microfluidic chip system of claim 1, wherein the plurality of imprinted sites on the surface of the molecularly imprinted biosensor is formed by processing the steps of polymer combination, polymerization, and extraction in order.

10. The anesthetic sensing optical microfluidic chip system of claim 1, wherein the micro-channel is in the form of U.

11. The anesthetic sensing optical microfluidic chip system of claim 1, further comprising:
a processor, coupled to the detector, for receiving the detecting result from the detector and processing the detecting result to generate a real-time anesthetic concentration information according to the detecting result.

12. The anesthetic sensing optical microfluidic chip system of claim 11, wherein the anesthetic concentration is adjusted according to the real-time anesthetic concentration information generated by the processor.
